(19) United States
(12) Patent Application Publication
(10) Pub. No.: US 2026/0245829 A1
(43) Pub. Date: Aug. 20, 2026

(54) Device, Control Method for Same, and Program

(71) Applicant: Hitachi High-Tech Corporation, Minato-ku, Tokyo (JP)

(72) Inventors: Tatsuya USUI, Tokyo (JP); Nozomi KASAHARA, Tokyo (JP); Takumi UEZONO, Tokyo (JP); Hironori ITABASHI, Tokyo (JP); Masato KAMIO, Tokyo (JP); Keisuke TANUMA, Tokyo (JP); Ryuko UJIHIRA, Tokyo (JP)

(21) Appl. No.: 19/161,750

(22) PCT Filed: Jun. 23, 2023
(86) PCT No.: PCT/JP2023/023295

§ 371 Date: Sep. 3, 2025

(51) Int. Cl. H01J 37/28; H01J 37/22

(52) U.S. Cl. CPC H01J 37/28; H01J 37/222; H01J 2237/221; H01J 2237/2806; H01J 2237/2812

(57) ABSTRACT

A charged particle beam device 100 has an electron gun 102, a deflector 104, a detector 108, a sample stage 105 on which a sample 106 is placed, and a controller 109. Herein, the controller 109, upon receiving an instruction to create a captured image: (1) receives a VC method application region designation; (2) receives, from the detector, a secondary electron detection signal of the sample while sending a control signal generated on the basis of a predetermined scan trajectory to the deflector; and (3) generates a captured image on the basis of the secondary electron detection signal. The captured image includes a first partial region suitable for a VC method and a second partial region suitable for surface observation of the sample.

### TECHNICAL FIELD

The present invention relates to a device, a control method for the device, and a program, for example, a device such as an electron beam device, a semiconductor inspection device using the electron beam device, a control method for the device, and a program.

### BACKGROUND ART

PTL 1 discloses a technique related to a charged particle beam device which is an electron beam device. PTL 1 discloses a scanning electron microscope (hereinafter also referred to as SEM) that scans a sample a plurality of times with a charged particle beam, detects emitted electrons, and creates an output image. In addition, PTL 1 discloses creation of an image having a uniform luminance level in the entire field of view by normalizing a luminance value of each pixel in a scanning region by an irradiation time of the charged particle beam.

### CITATION LIST

### Patent Literature

PTL 1: JP2015-210903A

### SUMMARY OF INVENTION

### Technical Problem

A scanning electron microscope is used in a wide range of fields such as semiconductor device, electronic, advanced material, organism, and pharmaceutical. In particular, in the field of semiconductor device, a voltage contrast (hereinafter, also referred to as VC) method is also used in which a surface is irradiated with an electron beam, a voltage contrast generated by a potential difference generated on the charged surface is observed, and a failure or a defect is observed, in addition to general SEM observation along with miniaturization and complication of a semiconductor. However, since contrast sensitivity decreases with miniaturization of a semiconductor, it takes time to search for an optimum scanning parameter, and strict positioning is required at the time of observation, and extra processing such as preliminary observation for confirming position validity is required. It is expected that miniaturization and complication of a semiconductor will progress in the future, and improvement of contrast, shortening of observation time, and shortening of turnaround time (TAT) in the VC method are required.

The charged particle beam device described in PTL 1 normalizes a cumulative luminance value per unit area of a sample surface by a cumulative irradiation time of an electron beam onto the area when there is a region having a different scanning speed on a sample or a region in which secondary electrons are less likely to be generated in one captured image. This technique is a technique of matching luminance levels of images of respective regions having different scanning conditions when an amount of electrons radiated per unit area is different due to a difference in scanning conditions such as a scanning speed and repeated scanning. PTL 1 merely describes that the cumulative irradiation time of an electron beam is used to normalize the luminance level, and PTL 1 does not mention improvement in contrast, shortening of observation time, and shortening of TAT in the VC method. In addition, PTL 1 does not mention that a captured image is acquired in consideration of a shape, an area, a material, and the like of an observation target in VC observation.

An object of the invention is to provide a device and a control method for the device capable of improving contrast, shortening an observation time, and shortening a TAT.

Other objects and novel features of the invention will become apparent from description of the present description and the accompanying drawings.

### Solution to Problem

An overview of a representative embodiment disclosed in the present application will be briefly described as follows.

That is, a representative embodiment discloses a device including an electron gun, a deflector, a detector, a sample stage on which a sample is placed, and a controller. Here, the controller is configured to, upon receiving an instruction to create a captured image: (1) receive designation of a VC method application region; (2) send, to the deflector, a control signal generated based on a predetermined scanning trajectory, and receive, from the detector, a secondary electron detection signal from the sample; and (3) create the captured image based on the secondary electron detection signal. Here, the captured image includes a first partial region suitable for a VC method and a second partial region suitable for surface observation of the sample.

### Advantageous Effects of Invention

To briefly explain effects obtained by the representative embodiment among inventions disclosed in the present application, it is possible to provide a device and a control method for the device capable of improving contrast, shortening an observation time, and shortening a TAT.

### BRIEF DESCRIPTION OF DRAWINGS

FIG. 1 is a block diagram showing a configuration of a charged particle beam device according to an embodiment.

FIG. 2 is a timing chart showing a relationship between an image creation control signal and pixel data according to the embodiment.

FIG. 3 is a block diagram showing an example of a pixel coefficient storage unit according to the embodiment.

FIG. 4 is a block diagram showing an example of a pixel integration processing unit according to the embodiment.

FIG. 5 is a flowchart showing an operation of a controller according to the embodiment.

FIG. 6 is a plan view showing an example of a captured image acquired by scanning a sample by the charged particle beam device according to the embodiment.

FIG. 7 is a schematic plan view showing an example of a scanning pattern when the sample is scanned to acquire the captured image in FIG. 6.

### DESCRIPTION OF EMBODIMENTS

In the following embodiments, when referring to the number of elements or the like, the number of elements is not limited to a specific number, and may be the specific number or more or the specific number or less, unless otherwise specified or except a case where the number is apparently limited to a specific number in principle. In the following embodiments, the components are not necessarily essential unless specifically stated otherwise or unless it is clearly considered not to be essential in principle. Further, in the following embodiments, when referring to a shape, a positional relation, or the like of a component or the like, the shape or the like is substantially approximate or similar to the shape or the like unless otherwise specified or clearly considered otherwise in principle. The same applies to the above-described numerical value and range.

In all drawings for showing the embodiments, the same members are denoted by the same reference numerals in principle, and repeated description thereof will be omitted.

Hereinafter, embodiments will be described with reference to the drawings. In the following embodiments, a scanning electron microscope is described as an example of a charged particle beam device, but the invention is not limited to the scanning electron microscope and may be applied to other charged particle beam devices.

### Overview of Embodiment

In an embodiment, a case is described as an example in which a semiconductor device is observed, particularly, VC observation of the semiconductor device is performed using a charged particle beam device including a scanning electron microscope. When observation is performed by a VC method using the charged particle beam device, it is important to increase a contrast (luminance level) ratio between a captured image of a region to which the VC method is applied (hereinafter, also referred to as a VC method application region) and a captured image of a region to which the VC method is not applied (hereinafter, also referred to as a VC method non-application region). The captured image of the VC method non-application region corresponds to a captured image acquired by performing normal surface scanning on a region to which the VC method is not applied.

In the charged particle beam device according to the embodiment, a scanning speed can be freely changed on one scanning line. For example, scanning is performed at a first scanning speed in the VC method application region on a sample, and scanning is performed at a second scanning speed different from the first scanning speed in the VC method non-application region on the same line on the sample. When a captured image of a predetermined field of view of the charged particle beam device is one frame, a captured image including a partial image of the VC method application region and a partial image of the VC method non-application region in one frame is acquired by one scanning.

Here, a first pixel coefficient determined based on features such as a shape, a material, and an area of a plug in the VC method application region is integrated with pixel data of the partial image corresponding to the VC method application region on the sample. On the other hand, a second pixel coefficient determined based on the second scanning speed is integrated with pixel data of the partial image corresponding to the VC method non-application region on the sample.

As a result, according to the charged particle beam device in the embodiment, it is possible to acquire a captured image of one frame in an observation field of view (predetermined field of view) including the partial image of the VC method application region and the partial image of the VC method non-application region by one scanning, it is possible to grasp validity of a position of the VC method application region and a relationship with a structure on the other portion of the sample captured in the VC method non-application region, and it is possible to acquire a captured image at one time by normal scanning. Therefore, it is possible to omit a preliminary observation operation of performing observation by the VC method after confirming a position, and it is possible to shorten an observation time and shorten a TAT.

In addition, since the image of the VC method application region is created by integrating the pixel data with the first pixel coefficient in consideration of a charging feature such as a shape, a material, and an area of a plug in the VC method application region, it is possible to increase a contrast with the image of the VC method non-application region.

### Embodiment

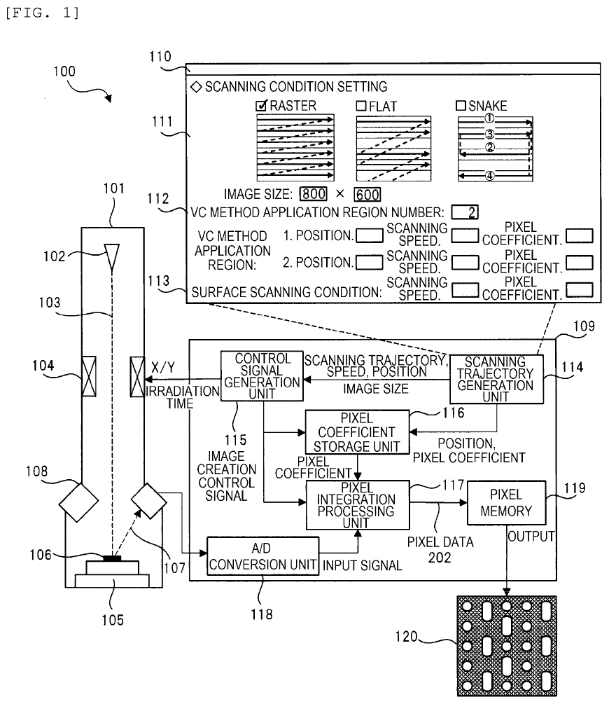

FIG. 1 is a block diagram showing a configuration of a charged particle beam device according to an embodiment. In FIG. 1, a reference numeral 100 denotes a charged particle beam device according to Embodiment 1. The charged particle beam device 100 includes a scanning electron microscope 101 and a controller 109 that controls the scanning electron microscope 101.

### <Scanning Electron Microscope>

The scanning electron microscope 101 includes an electron gun 102, a scanning deflector (hereinafter, also simply referred to as a deflector) 104, a sample stage 105, and a detector 108.

An electron beam 103 emitted from the electron gun 102 is deflected by the deflector 104 and focused on a sample 106 placed on the sample stage 105. The sample 106 is irradiated with the electron beam 103 to emit secondary electrons 107. The emitted secondary electrons 107 are detected by the detector 108 and transmitted to the controller 109 as a detection signal. The controller 109 executes signal processing on the received detection signal to create a captured image 120 of the sample 106.

FIG. 1 shows a pair of deflectors 104 facing each other in order to avoid complication of the drawing, but specifically, two pairs of deflectors 104 substantially orthogonal to each other are provided in the scanning electron microscope 101. The two pairs of deflectors 104 include a pair of deflectors (X-direction deflectors) that perform scanning with the electron beam 103 in an X direction and a pair of deflectors (Y-direction deflectors) that perform scanning with the electron beam 103 in a Y direction on the sample 106. A control signal is supplied from the controller 109 to the X-direction deflectors and the Y-direction deflectors, and the X-direction deflectors and the Y-direction deflectors deflect the electron beam 103 according to the control signal from the controller 109. The control signal from the controller 109 includes an X/Y control signal (indicated as X/Y in FIG. 1) for instructing movement of the electron beam 103 in the X direction and the Y direction, and an electron beam irradiation time signal (indicated as irradiation time in FIG. 1) for instructing an irradiation time during which the sample 106 is irradiated with the electron beam 103. The deflector 104 controls the electron beam 103 according to the X/Y control signal and the electron beam irradiation time signal.

### <Controller>

Next, the controller 109 will be described. The controller 109 controls scanning of an electron beam in the scanning electron microscope 101 based on a scanning condition and a parameter set by a user (not shown), and creates a captured image based on a detection signal from the scanning electron microscope 101.

First, setting of the scanning condition and the parameter by a user will be described. Here, an example is described in which a user sets (instructs) the scanning condition and the parameter to the controller 109 using an input device (not shown) and a display device (not shown) connected to the controller 109. Although not particularly limited, a case is described here in which the user sets the scanning condition and the parameter using a graphic user interface (GUI). It is needless to say that a method of setting the scanning condition and the parameter is not limited thereto, and the user can perform the setting while performing checking by using the GUI, and the setting becomes easy.

### <<GUI Screen>>

In FIG. 1, a reference numeral 110 denotes a GUI screen displayed on the display device by the controller 109. The user operates the input device such as a mouse and a keyboard to select an item displayed on the GUI screen 110 or input a numerical value.

In the embodiment, although not particularly limited, one GUI screen 110 includes three regions 111, 112, and 113 and an image size designation region.

### <<<Region 111: Scanning Method>>>

The user selects a scanning method of the electron beam 103 in the region 111. That is, in the example shown in FIG. 1, the scanning method includes three scanning methods of raster, flat, and snake. The user selects one scanning method from the three scanning methods in the region 111. The electron beam 103 is deflected by a deflector so as to move along a trajectory (scanning trajectory) determined by the selected scanning method. In the example shown in FIG. 1, the raster is selected as the scanning method of the electron beam 103, and a raster trajectory is selected as the scanning trajectory.

### <<<Region 112: VC Method Application Region>>>

In the region 112, the user sets a parameter (inputs a numerical value) related to scanning of the VC method application region. The number of the VC method application regions set on the sample 106 is not limited to one. That is, a plurality of VC method application regions may be set on the sample 106. In the region 112 shown in FIG. 1, there is a VC method application region number which is a region for designating the number of the VC method application regions, and a numerical value “2” is set. Accordingly, two VC method application regions can be set. It is needless to say that the numerical value set as the VC method application region number may be “1” or “3” or more.

In the embodiment, parameters of the VC method application region include information on a position of the VC method application region on the sample 106 (position and display in FIG. 1), an irradiation time for irradiating a surface of the sample 106 corresponding to each pixel in the VC method application region with the electron beam 103, and a pixel coefficient of each pixel of a captured image corresponding to a position irradiated with the electron beam 103 on the sample 106. Since scanning of a next pixel is performed after a numerical value set to the irradiation time described above, the irradiation time can be regarded as a scanning speed, and is indicated as a scanning speed in FIG. 1.

As a method of setting the scanning speed and the pixel coefficient for each pixel of the VC method application region, a numerical value may be directly input on the GUI screen 110 using the input device. Alternatively, for example, a setting file in which each parameter is described for each pixel in advance may be prepared and the setting file may be read by the controller 109. Here, as the pixel coefficient in the VC method application region, a parameter is set in consideration of a shape, an area, a material, and the like of a plug in a portion of the sample 106 corresponding to each target pixel. Accordingly, the pixel coefficient is a coefficient that does not depend on a scanning speed. That is, as the pixel coefficient, a coefficient that does not depend on a scanning speed and determined in consideration of features in the VC method application region of the sample 106 is used, both the irradiation time and a VC contrast of a captured image can be optimized, a TAT of observation can be shortened, and observation accuracy can be improved.

For example, by reducing a scanning speed in the VC method application region, it is possible to increase the irradiation time of the electron beam in the VC method application region and increase a contrast of the VC method application region relative to the VC method non-application region. However, for example, when the VC method application region is small and the irradiation time is long, it is considered that there is damage to the VC method application region, and it is not desirable to reduce the scanning speed. On the other hand, in the embodiment, a pixel coefficient that does not depend on a scanning speed and determined in consideration of a shape, an area, a material, or the like is integrated with a pixel of the VC method application region, and a captured image of the VC method application region is acquired. By using an appropriate pixel coefficient that increases an integrated value, it is possible to improve (increase) a contrast of the VC method application region relative to the VC method non-application region while increasing the scanning speed and shortening the irradiation time.

As a method in which a user sets a position of the VC method application region, a numerical value may be directly input on the GUI screen 110 using the input device. Alternatively, for example, design data of the sample 106 may be read and a predetermined position in the design data may be set as information related to the position of the VC method application region, or a position on the sample 106 may be set as a known marker, and a relative position from the marker to a predetermined position may be set as information related to the position of the VC method application region.

### <<<Region 113: VC Method Non-Application Region>>>

In the region 113, the user sets a parameter related to scanning of a VC method non-application region. The VC method non-application region corresponds to a region where normal surface scanning is performed, and the user sets a parameter (inputs a numerical value) related to scanning of the region where normal surface scanning is performed in the region 113. Parameters of the region where normal surface scanning is performed include, for example, a scanning speed and a pixel coefficient, and the user sets these parameters in the region 113. It is needless to say that the scanning speed and the pixel coefficient may be changed for each pixel.

### <<<Image Size Designation Region>>>

In addition to the three regions described above, for example, there is a region for designating a size of a captured image to be acquired (image size) on the GUI screen 110 as an item set by the user. In the example of FIG. 1, the user directly inputs a numerical value of 800×600 as the image size in the image size designation region.

### <<Configuration of Controller>>

Next, a configuration example of the controller 109 will be described. The controller 109 includes a scanning trajectory generation unit 114, a control signal generation unit 115, a pixel coefficient storage unit 116, a pixel integration processing unit 117, an A/D (analog to digital) conversion unit 118, and a pixel memory 119. The controller 109 includes a processor, and the processor executes programs stored in a nonvolatile memory (not shown) to implement the scanning trajectory generation unit 114, the control signal generation unit 115, the pixel coefficient storage unit 116, the pixel integration processing unit 117, and the like. An example of the processor includes a CPU or a GPU, or another semiconductor device may be used as long as the processor is a subject that executes predetermined processing. It is needless to say that these units may be implemented by combining logic circuits, sequential circuits, and the like.

The scanning condition and the parameter set by the user on the GUI screen 110 are read into the scanning trajectory generation unit 114 when the setting is completed. The scanning trajectory generation unit 114 supplies parameters of a scanning trajectory (scanning method), a scanning speed, a position of a scanning region, and an image size among the read scanning condition and parameter to the control signal generation unit 115, and supplies the parameters of the position of the scanning region and the pixel coefficient to the pixel coefficient storage unit 116. Here, the position of the scanning region indicates a position of the VC method application region and a position of the VC method non-application region. Hereinafter, in the present specification, when the VC method application region and the VC method non-application region are not distinguished from each other, they are also referred to as a scanning region.

The control signal generation unit 115 inputs a control signal (X/Y control signal: X/Y) for controlling the deflector 104 and an electron beam irradiation time signal (irradiation time) calculated based on the scanning time to the scanning electron microscope 101. At the same time, the control signal generation unit 115 supplies an image creation control signal for creating a captured image of the sample 106 to the pixel coefficient storage unit 116 and the pixel integration processing unit 117 to control creation of the captured image.

The pixel coefficient storage unit 116 stores pixel coefficients set by the user and sequentially outputs the stored pixel coefficients to the pixel integration processing unit 117. The position and the pixel coefficient read by the scanning trajectory generation unit 114 and the image creation control signal generated by the control signal generation unit 115 are supplied to the pixel coefficient storage unit 116.

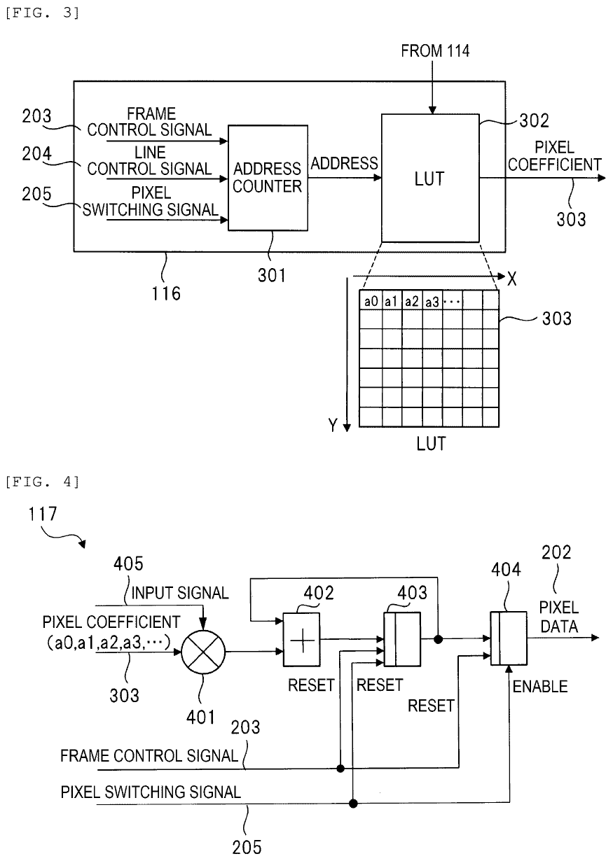

As will be described later in detail with reference to FIG. 3, the pixel coefficient storage unit 116 includes a look up table (hereinafter also referred to as LUT). The pixel coefficients supplied to the pixel coefficient storage unit 116 are stored and held in the LUT. The LUT has at least the same number of elements as the number of pixels of one frame of the captured image, and a pixel coefficient of a pixel set (designated) by the user is stored in an element of the LUT at coordinates corresponding to coordinates of the pixel of the captured image. The pixel coefficient storage unit 116 monitors the image creation control signal from the control signal generation unit 115, updates a coordinate address indicating an element of the current LUT when it is determined that integration processing for a current pixel is completed, and outputs the pixel coefficient stored in the element of the LUT indicated by the updated coordinate address.

The A/D conversion unit 118 converts a detection signal based on the secondary electrons 107 from the detector 108 into a digital signal and outputs the digital signal as an input signal.

The pixel integration processing unit 117 executes the integration processing on the input signal converted into the digital signal by the A/D conversion unit 118 based on the image creation control signal and the pixel coefficient, stores, in the pixel memory 119, pixel data 202 obtained by integrating the input signal by the number of times of integration calculated from a scanning speed designated by the user, and outputs the acquired captured image 120 when scanning of one frame is completed.

The completion of the setting of the scanning condition and the parameter and the reading by the scanning trajectory generation unit 114 can be regarded as an instruction to the controller 109 to create the captured image 120. The reading of the setting related to the VC method application region can be regarded as reception of designation of the VC method application region by the controller 109.

### <<<Image Creation Control Signal and Pixel Data>>>

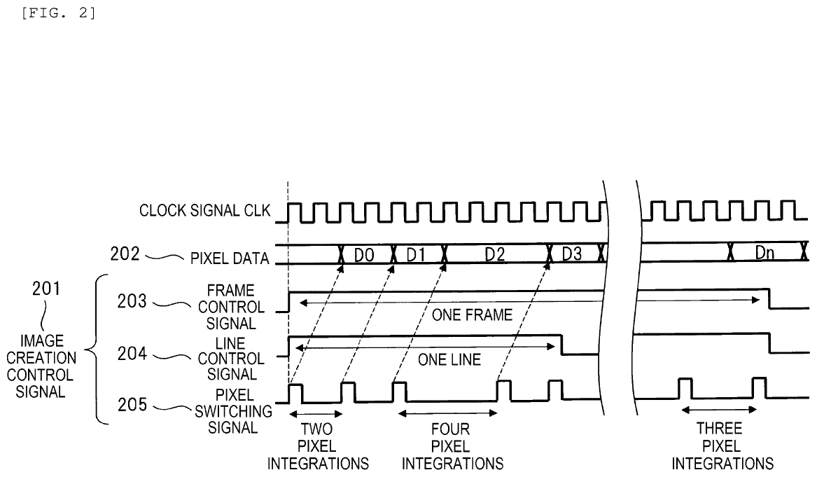

Next, a timing of the image creation control signal and the pixel data 202 will be described with reference to the drawings. FIG. 2 is a timing chart showing a relationship between the image creation control signal and the pixel data according to the embodiment. In FIG. 2, a horizontal axis represents time, and a vertical axis represents voltage. A clock signal CLK shown in FIG. 2 indicates a reference clock signal. Although not particularly limited, the controller 109 operates in synchronization with the clock signal CLK.

As shown in FIG. 2, the image creation control signal 201 includes a frame control signal 203, a line control signal 204, and a pixel switching signal 205, and each of these signals (203 to 205) changes based on a rising edge (hereinafter, also simply referred to as rising) of the clock signal CLK.

Each of the frame control signal 203, the line control signal 204, and the pixel switching signal 205 is generated by the control signal generation unit 115 shown in FIG. 1.

The frame control signal 203 is asserted (high level) at the start of scanning. A period in which the frame control signal 203 is continuously asserted indicates that a region in the same frame is scanned. When the scanning of the entire one frame is completed, the frame control signal 203 is negated.

The line control signal 204 is a signal indicating line switching in scanning. The line control signal 204 is asserted at the start of scanning for each line, and is negated when scanning of the one line is completed. For example, when a raster (trajectory) is set as a scanning method (scanning trajectory), the line control signal 204 is asserted during scanning of one line, and the line control signal 204 is negated when scanning of one line is completed. Thereafter, a direction of the deflector 104 is controlled to a scanning start position of a next line, and the line control signal 204 is continuously negated during a period (blanking period) up to the start of scanning.

The pixel switching signal 205 is a control signal indicating switching of a pixel. The pixel switching signal 205 is asserted by one pulse when the irradiation of the electron beam 103 for the irradiation time calculated based on the scanning speed set (designated) by the user is completed for a region on the sample 106 corresponding to one pixel. The number of cycles of the clock signal CLK from a rising edge of the previous pixel switching signal 205 to a rising edge of the next pixel switching signal 205 is the number of times of integration for each pixel in the pixel integration processing unit 117.

That is, when a scanning speed for a region (VC method application region) designated by the user is high and an irradiation time of a beam to a surface of the region on the sample 106 is short, an interval (interval between rising edges) of the pixel switching signal 205 is short, and the number of times of integration for each pixel in the pixel integration processing unit 117 also decreases. On the other hand, when the scanning speed designated by the user is low, since an irradiation time of a beam to a surface of the region of the sample 106 is long, the interval of the pixel switching signal 205 is long, and the number of times of integration for each pixel in the pixel integration processing unit 117 also increases.

The pixel data 202 is data obtained by performing the integration processing on an input signal obtained by converting a detection signal from the detector 108 into a digital signal by the A/D conversion unit 118 for the number of cycles of the clock signal CLK until the pixel switching signal 205 is asserted again using a pixel coefficient designated by the user. For example, the pixel data 202 indicated by “DO” indicates a value (two pixel integrations) obtained by integrating a pixel coefficient with the input signal for two cycles of the clock signal CLK. Similarly, the pixel data 202 indicated by “D2” indicates a value (four pixel integrations) obtained by integrating a pixel coefficient with the input signal for four cycles of the clock signal CLK.

### <<<Pixel Coefficient Storage Unit>>>

FIG. 3 is a block diagram showing an example of the pixel coefficient storage unit according to the embodiment. As shown in FIG. 3, the pixel coefficient storage unit 116 includes at least an address counter 301 and an LUT 302.

As shown in a lower part of FIG. 3, in the LUT 302, a plurality of elements are stored at addresses (intersections of X coordinates and Y coordinates) of an array specified by the X coordinates (X) and the Y coordinates (Y). An array including the X coordinates and the Y coordinates corresponds to one frame. That is, pixels in one frame respectively correspond to the addresses specified by the X coordinates and the Y coordinates, and the elements stored in the addresses correspond to the pixels.

In each address of the LUT 302, a pixel coefficient 303 for each pixel set by the user on the GUI screen 110 is stored as an element. That is, the LUT 302 stores the pixel coefficient 303 from the scanning trajectory generation unit 114. At this time, a stored address in the LUT 302 is determined by a parameter indicating a position of a scanning region from the scanning trajectory generation unit 114. In FIG. 3, “a0” to “a3” shown as the pixel coefficients 303 correspond to the pixel data “DO” to “D3” shown in FIG. 2. That is, “a0” is a pixel coefficient corresponding to the pixel data “DO”, and “a2” is a pixel coefficient corresponding to the pixel data “D2”.

The frame control signal 203, the line control signal 204, and the pixel switching signal 205 are supplied to the address counter 301. The address counter 301 generates an address for specifying an element of LUT 302 based on these signals. A pixel coefficient stored in the LUT 302 is selected according to the address generated by the address counter 301, and the selected pixel coefficient is output from the pixel coefficient storage unit 116 as the pixel coefficient 303.

The address generated by the address counter 301 is also used as an address indicating an element of the image memory 119 shown in FIG. 1. That is, in the image memory 119, the corresponding pixel data 202 is stored at an address specified by the address generated by the address counter 301.

### <<<Pixel Integration Processing Unit>>>

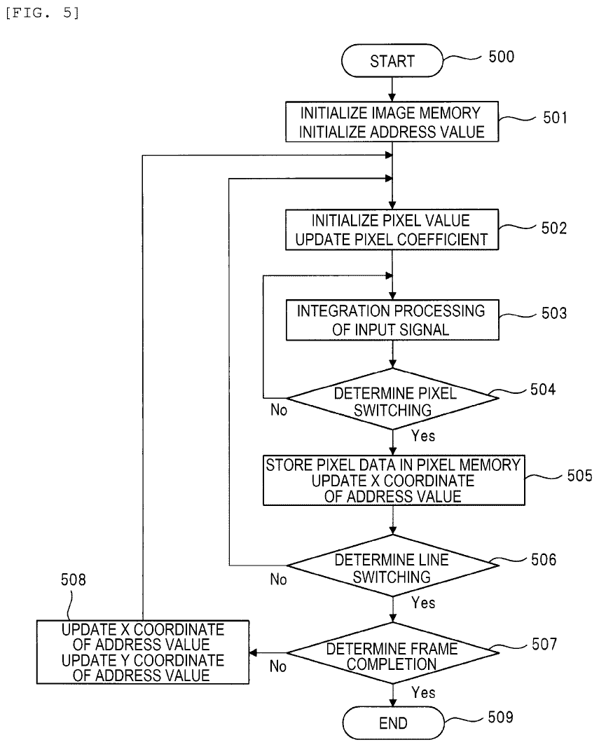

FIG. 4 is a block diagram showing an example of the pixel integration processing unit according to the embodiment. As shown in FIG. 4, the pixel integration processing unit 117 includes at least a multiplier 401, an adder 402, a flip-flop circuit (hereinafter, also referred to as an FF circuit) 403 that stores data during the integration processing, and a latch circuit 404 that stores the data subjected to the integration processing and outputs the data as pixel data to the image memory 119. The pixel integration processing unit 117 receives at least an input signal 405 acquired by converting a secondary electron signal detected by the detector 108 (FIG. 1) into a digital signal by the A/D conversion unit 118 (FIG. 1), the pixel coefficient 303 output from the pixel coefficient storage unit 116 (FIG. 3), the frame control signal 203, and the pixel switching signal 205.

The multiplier 401 performs multiplication between the input signal 405 and the pixel coefficient 303, and outputs a multiplication result to the adder 402. The adder 402 adds a previous multiplication result stored in the FF circuit 403 and a current multiplication result, and updates a value stored in the FF circuit 403 with an addition result.

The frame control signal 203 is input to each of the FF circuit 403 and the latch circuit 404, and each of the FF circuit 403 and the latch circuit 404 is reset by a rising edge of the frame control signal 203. The FF circuit 403 is also reset by a rising edge of the pixel switching signal 205. On the other hand, the latch circuit 404 is enabled by a rising edge of the pixel switching signal 205.

Since the FF circuit 403 is reset by the rising of the frame control signal 203, the FF circuit 403 is reset at the start of one frame. The FF circuit 403 is also reset by the rising of the pixel switching signal 205. In other words, the addition result of the adder 402 is accumulated in the FF circuit 403 during a period from the rising of the pixel switching signal 205 to next rising.

For example, when the pixel data 202 is “DO”, as shown in FIG. 2, after rising, the pixel switching signal 205 rises again after two cycles of the clock signal CLK. Accordingly, at the time of the clock signal CLK of the first cycle, the input signal 405 and “a0” of the pixel coefficient 303 are multiplied by the multiplier 401, and a multiplication result and an output of the reset FF circuit 403 are added by the adder 402 and stored in the FF circuit 403. At the time of the clock signal CLK of the second cycle, the input signal 405 and “a0” of the pixel coefficient 303 are multiplied by the multiplier 401, and a multiplication result and the multiplication result of the first cycle stored in the FF circuit 403 are added by the adder 402 and stored in the FF circuit 403. Although the case where the pixel data 202 is “DO” is described as an example, in other cases (for example, D1 to D3), the accumulated number of times is determined according to a rising interval of the pixel switching signal 205 (the number of cycles of the clock signal CLK) in a similar manner.

Since the latch circuit 404 is also reset by the rising of the frame control signal 203, the latch circuit 404 is reset at the start of one frame. Thereafter, the latch circuit 404 is enabled by the rising of the pixel switching signal 205. When the latch circuit 404 is enabled, the latch circuit 404 takes an output of the FF circuit 403 and outputs the output of the FF circuit 403 as the pixel data 202.

In FIGS. 3 and 4, “a0” to “a3” indicate pixel coefficients (first pixel coefficients) set based on features of the VC method application region. In this case, positions of the VC method application region on the sample 106 is (X0, Y0) to (X3, Y0) when represented by X coordinates and Y coordinates. Although not shown in FIGS. 3 and 4, a pixel coefficient (second pixel coefficient) set for the VC method non-application region is also stored in the LUT and integrated with an input signal in the pixel integration processing unit 117 shown in FIG. 4. For the VC method non-application region, a scanning speed is set to, for example, one cycle of the clock signal CLK, and the second pixel coefficient is set based on the scanning speed.

The VC method non-application region is, for example, the entire region excluding the VC method application region in one frame. Accordingly, as shown in FIG. 1, it is not necessary to set a position of the VC method non-application region.

### <<<Processing Flow>>>

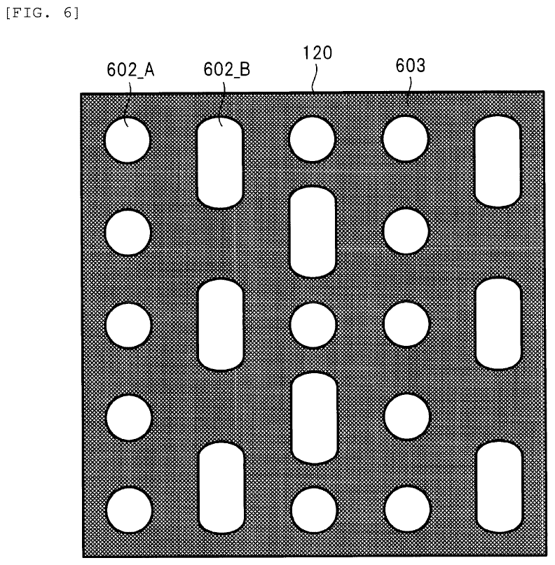

FIG. 5 s a flowchart showing an operation of the controller according to the embodiment. Next, operations of the pixel coefficient storage unit and the pixel integration processing unit according to Embodiment 1 will be described with reference to FIG. 1 and FIGS. 3 to 5. Here, a case where a user sets the raster trajectory as shown in FIG. 1 as a scanning trajectory will be described as an example. It is needless to say that the raster trajectory is an example and the scanning trajectory is not limited thereto. Further, it is assumed that the pixel coefficient is supplied from the scanning trajectory generation unit 114 to the LUT 302 of the pixel coefficient storage unit 116, and the pixel coefficient was already stored in each element of the LUT 302.

First, in step 500, the controller 109 starts scanning.

Next, in step 501, the controller 109 asserts the frame control signal 203 and initializes the image memory 119. In addition, the controller 109 initializes an address (address value indicating an X coordinate and a Y coordinate) of the address counter 301 in the pixel coefficient storage unit 116. Accordingly, an address value for specifying an element of the image memory 119 and an element of the LUT 302 is initialized.

In step 502, the controller 109 uses the address counter 301 to select an element specified by the address value initialized in step 501 from elements of LUT 302 in the pixel coefficient storage unit 116, reads (updates) the pixel coefficient 303 stored in the selected element, and in response to the rising of the frame control signal 203, initializes the FF circuit 403 and initializes the pixel data (pixel value) 202 latched in the latch circuit 404 in the pixel integration processing unit 117.

Thereafter, in step 503, the controller 109 causes the pixel integration processing unit 117 to execute the integration processing using the read pixel coefficient 303 and the input signal. That is, the multiplier 401, the adder 402, and the FF circuit 403 shown in FIG. 4 are used to execute the integration processing. Every time the integration processing is completed, the controller 109 determines in step 504 whether the pixel switching signal 205 is asserted. In other words, the controller 109 determines whether the pixel switching signal 205 rises every time the clock signal CLK shown in FIG. 2 rises.

When it is determined in step 504 that the pixel switching signal 205 is not asserted (No), the controller 109 repeats the integration processing in step 503 until the pixel switching signal 205 is asserted, and acquires an integrated value. In other words, multiplication is performed between the same pixel coefficient and the same input signal by the number of cycles of the clock signal CLK from when the pixel switching signal 205 is asserted up to when the pixel switching signal 205 is asserted again after being negated, and a multiplication result is added to a previous multiplication result to obtain the integrated value.

When the pixel switching signal 205 is asserted in step 504 (Yes), in step 505, the controller 109 enables the latch circuit 404, updates the latch circuit 404, updates the pixel data 202, and stores the pixel data 202 in the pixel memory 119. That is, the updated pixel data 202 is stored in the pixel memory 119, and a current address value (X coordinate) is updated. At this time, the pixel data 202 stored in the pixel memory 119 is pixel data acquired by executing the integration processing between the pixel coefficient and the input signal by the number of cycles of the clock signal CLK at an interval of the rising edge of the pixel switching signal 205 in the pixel integration processing unit 117.

Next, in step 506, the controller 109 determines the presence or absence of line switching based on the line control signal 204. When the line control signal 204 is not negated, the controller 109 determines that there is no line switching, returns the processing to step 502, and executes processing. That is, the controller 109 initializes a pixel value and updates a pixel coefficient in step 502, executes the integration processing using the updated pixel coefficient and the updated input signal in steps 503 and 504, and stores the pixel data acquired by the integration processing in an address value updated in step 505.

The update of the address value in step 505 is performed by updating an address generated by the address counter 301 in the pixel coefficient storage unit 116 in response to the rising edge of the pixel switching signal 205. For example, when a current address (X coordinate, Y coordinate) generated by the address counter 301 is an address value (X0, Y0), the address counter 301 updates the address to an address value (X1, Y0) in response to the rising edge of the pixel switching signal 205. A control signal (X/Y control signal) output by the control signal generation unit 115 to control the deflector 104 corresponds to an address generated by the address counter 301. Therefore, when the address value generated by the address counter 301 is updated, a position irradiated with the electron beam 103 on the sample 106 also changes accordingly, and an input signal obtained based on secondary electrons from the position irradiated with the electron beam 103 is output from the A/D conversion unit 118. Therefore, when the address value generated by the address counter 301 is updated, an input signal input to the multiplier 401 is also updated. That is, the updated pixel coefficient and the input signal corresponding to the secondary electrons at a position on the sample 106 corresponding to the updated address value are supplied to the multiplier 401, and multiplication is performed between the updated pixel coefficient and the input signal.

On the other hand, in step 506, when the line control signal 204 is negated and the controller 109 determines that there is line switching, the controller 109 next executes step 507. In step 507, the controller 109 determines whether scanning for one frame is completed based on the frame control signal 203.

In step 507, when the frame control signal 203 is not negated, the controller 109 determines that scanning for one frame is not completed, and then executes step 508.

In step 508, the controller 109 initializes and updates an address generated by the address counter 301. That is, the address counter 301 updates an address value of a Y coordinate and initializes an address value of an X coordinate in response to the assertion of the line control signal 204. That is, the address counter 301 initializes a value of the X coordinate indicating a position of a pixel and updates a value of the Y coordinate indicating a position of a line, specifically, the address counter 301 outputs an address value (for example, X0, Y1) in which a position of the line and a position of the pixel are changed.

After step 508, steps 502 to 507 described above are executed. At this time, in step 502, the pixel coefficient designated by the address value (X0, Y1) in the LUT 302 is read, and an input signal input to the multiplier 401 is a signal based on secondary electrons at a position on the sample 106 designated by an X/Y control signal corresponding to the address value (X0, Y1).

When scanning for one frame is completed, the frame control signal 203 is negated. When scanning of one frame is completed, the controller 109 ends the pixel integration processing in step 509. The pixel data 202 for one frame generated by the pixel integration processing is stored in the image memory 119 and output to, for example, a display device as a captured image by scanning.

### <<<Captured Image>>>

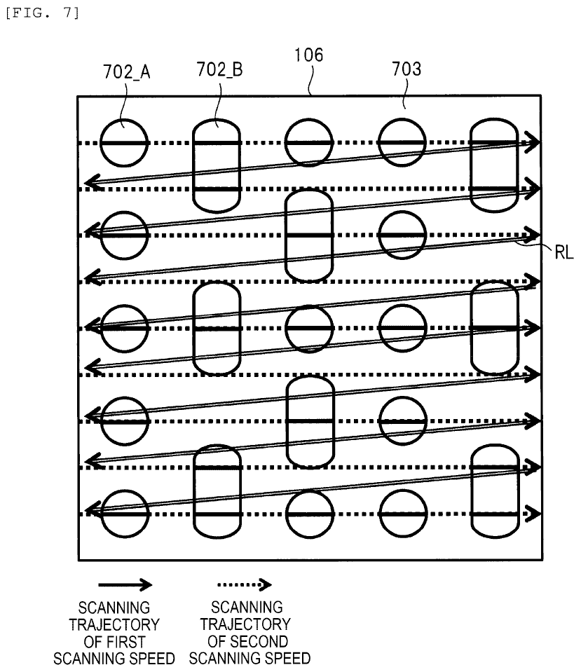

An example of a captured image captured by the charged particle beam device 100 according to the embodiment will be described below. FIG. 6 is a plan view showing an example of a captured image acquired by scanning a sample once by the charged particle beam device according to the embodiment. FIG. 7 is a schematic plan view showing an example of a scanning pattern when a sample is scanned to acquire the captured image in FIG. 6. FIGS. 6 and 7 show a case where a user sets a scanning condition on the GUI screen 110 as shown in FIG. 1. That is, a scanning trajectory is set to a raster trajectory as shown in FIG. 1.

FIGS. 6 and 7 show a case where a plurality of VC method application regions having a plurality of different areas and shapes and a VC method non-application region are set in a region of the sample 106 where scanning is performed once as one frame.

That is, in FIG. 6, a reference numeral 120 denotes a captured image of one frame acquired by one scanning, reference numerals 602_A and 602_B denote partial images of the VC method application regions having different areas and shapes, and a reference numeral 603 denotes a normal surface scanning partial image of the VC method non-application region.

In order to acquire the captured image as shown in FIG. 6, in the charged particle beam device 100 according to Embodiment 1, a surface of the sample 106 is scanned with a scanning pattern as shown in FIG. 7. That is, in VC method application regions 702_A and 702_B on the sample 106 corresponding to the partial images 602_A and 602_B, scanning using the electron beam 103 is performed at a first scanning speed, and in a VC method non-application region 703 on the sample 106 corresponding to the normal surface scanning partial image 603, scanning using the electron beam 103 is performed at a second scanning speed different from the first scanning speed. Here, it is assumed that the second scanning speed is set to a value higher than a value of the first scanning speed. In FIG. 7, a double arrow line RL indicates a return line, and the return line RL is a portion where a raster trajectory is switched and is a trajectory that does not affect acquisition of a captured image.

In the charged particle beam device according to the embodiment, when the VC method application regions 702_A and 702_B are set on the sample 106, a user can freely set a position of each of the VC method application regions 702_A and 702_B, a scanning speed for each pixel when each of the regions is scanned, and a pixel coefficient when each of the regions is scanned. On the sample 106, the user can also freely set a scanning speed for each pixel in the VC method non-application region 703 when the region is scanned and a pixel coefficient when the region is scanned. By setting the scanning speed and the pixel coefficient for the VC method application region and the scanning speed and the pixel coefficient for the VC method non-application region to appropriate values, the user can acquire a captured image with an improved VC contrast which is a ratio between the VC method application region and the VC method non-application region.

FIG. 7 shows an example in which the same first scanning speed is set for the plurality of VC method application regions 702_A and 702_B, but the invention is not limited thereto. That is, when there are a plurality of VC method application regions (701_A and 701_B) on the sample 106 as shown in FIG. 7, first scanning speeds having different values may be set for the VC method application regions.

In FIG. 7, a plurality of VC method application regions and the VC method non-application region are set on the same scanning trajectory (line). With such a setting, a scanning speed of the electron beam changes between the first scanning speed and the second scanning speed on the same scanning trajectory.

It is possible to acquire the partial images 602_A and 602_B of the VC method application regions and the normal surface scanning partial image 603 of the VC method non-application region by one scanning as shown in FIG. 7 and create the captured image 120 of one frame as shown in FIG. 6. Accordingly, since a step of preliminary observation required when VC observation is performed in the related art can be omitted, it is possible to achieve a short TAT of semiconductor observation, and it is possible to grasp validity of a position of a structure appearing in a partial image in the VC method application region and a relationship with a position of a structure appearing in a partial image of the VC method non-application region where normal surface scanning is performed, thereby contributing to improvement in scanning convenience.

According to the embodiment, a user can freely set the pixel coefficient minute region on the sample corresponding to one pixel of a captured image, and a captured image with a good VC contrast can be acquired while shortening a beam irradiation time to the region. Furthermore, since a partial image of the VC method application region and a partial image of the VC method non-application region where normal surface scanning is performed can be acquired as a captured image of one frame by one scanning, steps such as preliminary observation and position validity confirmation can be omitted, scanning convenience can be improved, and an observation time can be shortened.

In FIG. 7, the VC method application regions 702_A and 702_B can be regarded as a first surface, and the VC method non-application region 703 can be regarded as a second surface. In this case, the first surface is scanned at the first scanning speed, and the second surface is scanned at the second scanning speed. In FIG. 7, a trajectory portion indicated by a solid line in which scanning is performed at the first scanning speed can be regarded as a first scanning trajectory (first speed trajectory), and a trajectory portion indicated by a broken line in which scanning is performed at the second scanning speed can be regarded as a second scanning trajectory (second speed trajectory).

As described above, for example, the user sets the scanning speed and the pixel coefficient (first pixel coefficient and second pixel coefficient) suitable for each of the VC method application region and the VC method non-application region on the GUI screen 110. The scanning speed and the pixel coefficient set for the VC method non-application region are, for example, a scanning speed and a pixel coefficient suitable for normal surface scanning (surface observation), and the pixel coefficient for the VC method non-application region is set based on the scanning speed of the VC method non-application region.

In the first speed trajectory, scanning is performed at a scanning speed suitable for the VC method, and an image (the partial images 602_A and 602_B) of a first partial region corresponding to the first surface is created according to an input signal based on secondary electrons from the first surface and a pixel coefficient suitable for the VC method. In the second speed trajectory, scanning is performed at a scanning speed suitable for normal surface scanning, and an image (the partial image 603) of a second partial region corresponding to the second surface is created according to an input signal based on secondary electrons from the second surface and a pixel coefficient suitable for normal surface scanning.

Although the invention made by the present inventors has been specifically described based on the embodiment, the invention is not limited to the embodiment, and it is needless to say that various modifications can be made without departing from the gist of the invention.

### REFERENCE SIGNS LIST

100 charged particle beam device
101 scanning electron microscope
102 electron gun
104 deflector
108 detector
106 sample
109 controller
110 GUI screen
114 scanning trajectory generation unit
115 control signal generation unit
116 pixel coefficient storage unit
117 pixel integration processing unit
118 A/D conversion unit
119 pixel memory

1. A device comprising:
an electron gun;
a deflector;
a detector;
a sample stage on which a sample is placed; and
a controller, wherein
the controller that received an instruction to create a captured image is configured to:
receive designation of a VC method application region,
send, to the deflector, a control signal generated based on a predetermined scanning trajectory, and receive, from the detector, a secondary electron detection signal from the sample, and
create the captured image based on the secondary electron detection signal, and
the captured image includes following partial regions:
a first partial region suitable for a VC method, and
a second partial region suitable for surface observation of the sample.

2. The device according to claim 1, wherein
the predetermined scanning trajectory includes
a first speed trajectory for scanning a first surface on the sample corresponding to the designation of the VC method application region at a first scanning speed suitable for the VC method, and
a second speed trajectory for scanning a second surface on the sample not corresponding to the designation of the VC method application region at a second scanning speed higher than the first scanning speed,
the creation of the captured image of the first partial region is performed using a first coefficient,
the creation of the captured image of the second partial region is performed using a second coefficient determined based on the second scanning speed, and
the first scanning speed and the first coefficient are values determined based on a feature of the first surface.

3. The device according to claim 2, wherein
each of the first scanning speed and the second scanning speed corresponds to a time during which the first surface and the second surface are irradiated with an electron beam from the electron gun.

4. The device according to claim 3, wherein
the predetermined scanning trajectory includes one line of one scanning with the electron beam, and
on the same one line, the first surface is scanned at the first scanning speed and the second surface is scanned at the second scanning speed.

5. The device according to claim 4, wherein
the captured image of the first partial region is created by calculation of pixel data related to the first surface based on the secondary electron detection signal and the first coefficient, and
the captured image of the second partial region is created by calculation of pixel data related to the second surface based on the secondary electron detection signal and the second coefficient.

6. The device according to claim 5, wherein
the captured image of the first partial region and the captured image of the second partial region are included in one frame acquired by one scanning with the electron beam.

7. The device according to claim 1, wherein
the instruction to create the captured image is performed on a GUI.

8. A control method for a device including an electron gun, a deflector, a detector, a sample stage on which a sample is placed, and a controller, the control method comprising:
executed by the controller,
sending, to the deflector, a control signal generated based on a predetermined scanning trajectory, and receiving, from the detector, a secondary electron detection signal from the sample;
creating a captured image based on the secondary electron detection signal;
creating a first image related to a first partial region designated as a VC method application region on the sample; and
creating a second image suitable for surface observation of the sample for a second partial region different from the first partial region.

9. The control method according to claim 8, comprising:
executed by the controller,
scanning a first surface on the sample corresponding to the first partial region designated as the VC method application region at a first scanning speed suitable for a VC method according to the control signal, and creating the first image based on pixel data acquired by the scanning and a first coefficient; and
scanning a second surface on the sample corresponding to the second partial region at a second scanning speed higher than the first scanning speed according to the control signal, and creating the second image based on pixel data acquired by the scanning and a second coefficient, wherein
the first scanning speed and the first coefficient are values determined based on a feature of the first surface.

10. A program for causing the controller to execute the control method according to claim 8.
